(19) United States
(12) Patent Application Publication
(10) Pub. No.: US 2021/0347957 A1
(43) Pub. Date: Nov. 11, 2021

(54) ORGANIC BARRIER FILM, PREPARATION METHOD OF ORGANIC BARRIER FILM, AND QUANTUM DOT DEVICE

(71) Applicant: Najing Technology Corporation Limited, Hangzhou, Zhejiang (CN)

(72) Inventors: Hailin WANG, Hangzhou, Zhejiang (CN); Qile HU, Hangzhou, Zhejiang (CN); Yongyin KANG, Hangzhou, Zhejiang (CN); Jiamin YE, Hangzhou, Zhejiang (CN)

(21) Appl. No.: 17/285,920

(22) PCT Filed: Oct. 28, 2019
(86) PCT No.: PCT/CN2019/113738

§ 371 Date: Apr. 16, 2021

(30) Foreign Application Priority Data
Oct. 29, 2018 (CN) 201811267839.6

(51) Int. Cl. C08J 7/043; C08J 7/054; C08J 7/048; B05D 3/06; C09J 133/24; C09J 175/04; C09J 133/04

(52) U.S. Cl. CPC C08J 7/043; C08J 7/054; C08J 7/048; H01L 51/502; C09J 133/24; C09J 175/04; C09J 133/04; B05D 3/067

(57) ABSTRACT

Disclosed are an organic barrier film, a preparation method of the organic barrier film, and a quantum dot device. The organic barrier film includes a substrate layer, an adhesive layer, and an oxygen barrier layer that are sequentially stacked. The oxygen barrier layer includes polyvinyl alcohol, and chemical cross-linking is formed between the adhesive layer and the oxygen barrier layer.

### TECHNICAL FIELD

The present disclosure relates to the field of quantum dot materials, in particular to an organic barrier film, a method for preparing the organic barrier film, and a quantum dot device.

### BACKGROUND

At present, quantum dot synthesis technology has been relatively mature, the efficiency and stability of quantum dots have reached the level of industrialization, the unique surface effect of quantum dots also determines its sensitivity to water vapor and oxygen, water vapor and oxygen will destroy the ligands on the surface of quantum dots and reduce the efficiency of quantum dots. Therefore, quantum dots can only exert their high quantum yield and stability under the conditions of absence of water and oxygen. At present, the main uses of quantum dots include quantum dot tube and quantum dot film. Quantum dot tube encapsulates quantum dot materials in a glass tube, and quantum dot film uses barrier films to encapsulate the quantum dot materials in the middle to form a sandwich structure. Because the production process of quantum dot film is simple, and the quantum dot film is bendable and can significantly improve the color gamut and color saturation of liquid crystal displays, quantum dot film has gradually become popular for quantum dot TV.

However, except the extreme importance of quantum dot materials, the barrier film is also very important in quantum dot film. The current main methods for preparation of barrier film are generally as follows: first laying an inorganic oxide layer on a polyester film substrate by evaporation, magnetron sputtering, or vacuum chemical deposition, and then coating the inorganic oxide layer with an organic layer. A barrier film including both an organic layer and an inorganic oxide layer has good barrier properties. The production process of this kind of barrier film is complicated and the cost is high. The inorganic oxide layer of the barrier film may be subjected to rupture and lose its barrier performance during the curling process.

### SUMMARY

In order to overcome the deficiencies of the prior art, the object of the present disclosure is to provide an organic barrier film, a method for preparing the organic barrier film, and a quantum dot device. The obtained organic barrier film has good oxygen and water resistance.

According to one aspect of the present disclosure, the present disclosure provides an organic barrier film including a substrate layer, an adhesive layer and an oxygen barrier layer that being sequentially stacked, the oxygen barrier layer includes a polyvinyl alcohol, and chemical cross-linking is formed between the adhesive layer and the oxygen barrier layer.

Further, the organic barrier film includes one of a hydrophobic layer disposed on surface of the substrate layer far away from the adhesive layer and a matte layer disposed on a surface of the substrate layer far away from the adhesive layer; preferably, the hydrophobic layer includes one or more of the following hydrophobic polymers: polyvinylidene chloride, polyvinylidene fluoride, polytetrafluoroethylene and polytrifluorochloroethylene; preferably, the matte layer includes a carrier and transparent particles.

Further, a raw material for preparing the adhesive layer includes a polymer binder, a crosslinker and a chelator, and chemical cross-linking is formed between the chelator and the polyvinyl alcohol; preferably, the polymer binder includes at least one of hydroxyl group, carboxyl group and amino group; more preferably, the polymer binder is selected from one or more of polyester, polyurethane and polyacrylate.

Further, the chelator is selected from one or more of boric acid, sodium borate, sodium acrylate and titanate.

Further, the crosslinker is selected from one or more of polycarbodiimide, aziridine and hexamethoxymethylmelamine.

Further, the glass transition temperature of the polymer binder is less than 50° C.

According to another aspect of the present disclosure, the present disclosure provides a method for preparing the organic barrier film, including steps of:

providing a substrate layer having a first surface and a second surface opposite from the first surface;

disposing an adhesive layer on the first surface, and disposing an oxygen barrier layer on a surface of the adhesive layer far away from the substrate layer, wherein the oxygen barrier layer includes polyvinyl alcohol, and chemical cross-linking is formed between the adhesive layer and the oxygen barrier layer.

Further, the preparation method of the adhesive layer includes: disposing a first mixture including a polymer binder, a crosslinker and a chelator on the first surface, and the chelator being used to form chemical cross-linking with the polyvinyl alcohol; preferably, the polymer binder includes at least one of hydroxyl group, carboxyl group, and amino group; more preferably, the polymer binder is selected from one or more of polyester, polyurethane, and polyacrylate.

Further, the chelator is selected from one or more of boric acid, sodium borate, sodium acrylate and titanate; preferably, the mass percentage of the chelator in the first mixture is 1% ˜10%.

Further, the crosslinker is selected from one or more of polycarbodiimide, aziridine and hexamethoxymethylmelamine.

Further, the preparation method further includes steps of: disposing a hydrophobic layer on the second surface, or disposing a matte layer on the second surface; preferably, the hydrophobic layer includes a hydrophobic polymer, and the hydrophobic polymer is selected from one or more of polyvinylidene chloride, polyvinylidene fluoride, polytetrafluoroethylene and polytrifluoroethylene; preferably, the matte layer includes a carrier and transparent particles.

Further, the preparation method of the oxygen barrier layer includes: disposing a second mixture on a surface of the adhesive layer far away from the substrate layer, and the second mixture including a polyvinyl alcohol, water, an antifoaming agent and a leveling agent.

According to another aspect of the present disclosure, the present disclosure provides a quantum dot device including a quantum dot layer and an organic barrier film disposed on at least one surface of the quantum dot layer, wherein the organic barrier film is the aforesaid organic barrier film, the organic barrier film includes a substrate layer, an adhesive layer and an oxygen barrier layer that are sequentially stacked, and the oxygen barrier layer is disposed on the surface of the adhesive layer close to the quantum dot layer.

Compared with the prior art, the beneficial effects of the present disclosure are:

(1) Polyvinyl alcohol is difficult to effectively adhere to the surface of most polyester films. In the present disclosure, the oxygen barrier layer including polyvinyl alcohol is bonded to the substrate layer through an adhesive layer. Chemical cross-linking is formed between the adhesive layer and the oxygen barrier layer, which improves the adhesion of the oxygen barrier layer to the surface of the substrate layer;

(2) The polyvinyl alcohol has excellent gas barrier performance, on the one hand, the regular molecular chain of polyvinyl alcohol makes its crystallinity very high, and on the other hand, the compact cross-linked network between molecules formed by a large number of hydroxyl hydrogen bonds has super strong barrier properties towards most gases. But its cross-linked hydrogen bonds are easily damaged by water vapor, which affects the barrier properties of the oxygen barrier layer. In the present disclosure, disposition of a hydrophobic layer on the outer surface of the substrate layer can effectively prevent the adsorption and dissolution of water vapor on the surface of the organic barrier film, and reduce the water vapor penetration of the system. In addition, the substrate layer also has a certain degree of water blocking function. The combination of the hydrophobic layer and the substrate layer can greatly reduce the water vapor penetrating into the oxygen barrier layer, so that the polyvinyl alcohol of the oxygen barrier layer maintains good barrier properties.

### BRIEF DESCRIPTION OF THE DRAWINGS

FIG. 1 is a schematic diagram of an embodiment of the organic barrier film of the present disclosure.

FIG. 2 is a schematic diagram of another embodiment of the organic barrier film of the present disclosure.

FIG. 3 is a schematic diagram of still another embodiment of the organic barrier film of the present disclosure.

In the figures: 1. Hydrophobic layer; 2. Substrate layer; 3. Adhesive layer; 4. Oxygen barrier layer; 5. Matte layer.

### DETAILED DESCRIPTION

The disclosure will be described in detail below with reference to the figures and in conjunction with the embodiments. It should be noted that the embodiments of the present disclosure and the features of the embodiments may be combined with each other in case of no conflict.

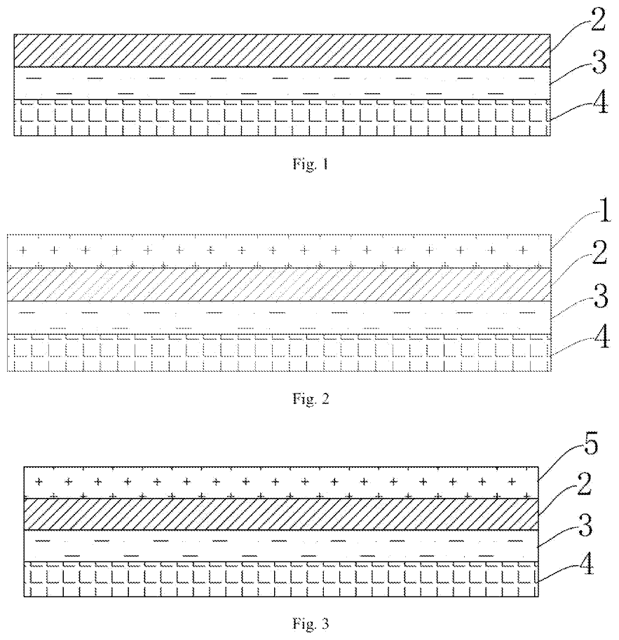

As shown in FIG. 1, the present disclosure provides an organic barrier film, including a substrate layer 2, an adhesive layer 3 and an oxygen barrier layer 4 that are sequentially stacked. The oxygen barrier layer 4 includes polyvinyl alcohol, and chemical cross-linking is formed between the adhesive layer 3 and the oxygen barrier layer 4.

The main function of the substrate layer 2 is to protect the oxygen barrier layer 4. The adhesive layer 3 is used to improve the adhesion between the substrate layer 2 and the oxygen barrier layer 4. Since the polyvinyl alcohol of the oxygen barrier layer 4 has poor adhesion with common adhesives, formation of chemical cross-linking between the adhesive layer 3 and the oxygen barrier layer 4 can improve the adhesion between the oxygen barrier layer 4 and the adhesive layer 3.

In some embodiments, as shown in FIG. 2, the organic barrier film further includes a hydrophobic layer 1, the hydrophobic layer 1 is disposed on the surface of the substrate layer 2 far away from the adhesive layer 3, and the hydrophobic layer 1 may include the following one or more hydrophobic polymers: polyvinylidene chloride, polyvinylidene fluoride, polytetrafluoroethylene, and polytrifluorochloroethylene. The hydrophobic layer 1 can effectively prevent the adsorption and dissolution of water vapor on the surface of the organic barrier film, and reduces the infiltration of water vapor.

In some other embodiments, as shown in FIG. 3, the organic barrier film further includes a matte layer 5, the matte layer 5 is disposed on the surface of the substrate layer 2 far away from the adhesive layer 3, and the matte layer 5 may include a carrier and transparent particles. The carrier can be selected from one or more of epoxy resin, acrylate resin, silicone resin and polyurethane resin, and the material of the transparent particles can be selected from one or more of polyacrylate, polystyrene, polypropylene, polycarbonate, methyl methacrylate-butadiene-styrene terpolymer and styrene-acrylonitrile copolymer. The matte layer 5 can be beneficial to increase the light transmission rate of the organic barrier film.

In some embodiments, the material of the substrate layer 2 can be polyethylene terephthalate (PET).

In some embodiments, the raw material of the adhesive layer 3 includes a polymer binder, a crosslinker and a chelator, and chemical cross-linking is formed between the chelator and the polyvinyl alcohol. In some embodiments, the polymer binder can be selected from one or more of polyester, polyurethane and polyacrylate. The polymer binder may contain at least one of the following groups: hydroxyl group, carboxyl group and amino group.

In some embodiments, in order to improve the adhesion between the polymer binder and the polyvinyl alcohol, the number of polar groups such as hydroxyl groups, carboxyl groups, and amino groups of the polymer binder can be high. And these polar groups can facilitate the spread of liquid polymer binder on the layer of polyvinyl alcohol to achieve a larger area of bonding. When the polar groups of the polymer binder are sufficient to exhibit a certain degree of hydrophilicity, the chelator and the crosslinker are required to be more uniformly dispersed in the liquid polymer binder. In some embodiments, the chelator and the crosslinker can be dissolved in the liquid polymer binder to achieve a uniform and reliable bonding.

The main function of the chelator is to form a bridge between the adhesive layer 3 and the oxygen barrier layer 4, thereby improving the adhesion between the adhesive layer 3 and the oxygen barrier layer 4.

In some embodiments, the chelator is selected from one or more of the following: boric acid, sodium borate, sodium acrylate and titanate. On the one hand, a certain extent of interaction exists between the chelator and the polymer binder, which makes the chelator difficult to separate from the polymer binder. The interaction between the chelator and the polymer binder could be embeddedness of crystalline of the former inside the latter, chemical cross-linking formed between the chelator and the polymer binder, or in other forms. On the other hand, the chemical cross-linking between the chelator and the polyvinyl alcohol forms the chemical crosslinking between the adhesive layer 3 and the oxygen barrier layer 4, which improves the adhesion between the adhesive layer 3 and the oxygen barrier layer 4.

In some embodiments, taking boric acid as the chelator, the chemical structure formed between the chelator and polyvinyl alcohol is as shown below:

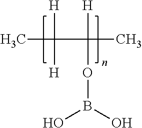

In some embodiments, the mass percentage of the chelator in the adhesive layer 3 is 1% to 10%, and as the amount of the chelator increases, the peeling force between the substrate layer 2 and the oxygen barrier layer 4 increases greatly.

The main function of the crosslinker is to improve the cohesion of the adhesive layer 3, thereby improving the water resistance and solvent resistance of the adhesive layer 3. The crosslinker can be selected from one or more of the following: polycarbodiimide, aziridine, and hexamethoxymethylmelamine.

In some embodiments, the polymer binder can be selected from one or more of hydroxyl-containing polyester, hydroxyl-containing polyurethane, and polyacrylate. In some embodiments, the glass transition temperature of the polymer binder is less than 50° C. Polymer in the form of emulsion with a low glass transition temperature and a large loss modulus is selected to be the polymer binder, which could improve its initial adhesion to the PET substrate layer 2.

The present disclosure also provides a method for preparing the organic barrier film, including the following steps:

providing a substrate layer 2 having a first surface and a second surface opposite from the first surface;

disposing an adhesive layer 3 on the first surface of the substrate layer 2, and disposing an oxygen barrier layer 4 on the surface of the adhesive layer 3 far away from the substrate layer 2, wherein the oxygen barrier layer 4 includes polyvinyl alcohol, and chemical cross-linking is formed between the adhesive layer 3 and the oxygen barrier layer 4.

In some embodiments, the preparation method of the adhesive layer 3 includes: disposing a first mixture including a polymer binder, a crosslinker, and a chelator on the first surface of the substrate layer 2, and the chelator can be used to form chemical cross-linking with polyvinyl alcohol.

In some embodiments, the aforesaid polymer binder includes at least one of the following groups: hydroxyl group, carboxyl group, and amino group. In some embodiments, the aforesaid polymer binder can be selected from one or more of polyester, polyurethane, and polyacrylate.

In some embodiments, when preparing the adhesive layer 3, the first mixture further includes a leveling agent and an antifoaming agent.

In some embodiments, the chelator may be selected from one or more of the following: boric acid, sodium borate, sodium acrylate, and titanate. In some embodiments, the mass percentage of the chelator in the above mixture is 1% to 10%.

The crosslinker can be selected from one or more of the following: polycarbodiimide, aziridine, and hexamethoxymethylmelamine.

In some embodiments, a hydrophobic layer 1 can be disposed on the first surface of the substrate layer 2. The hydrophobic layer 1 can be disposed on the surface of the substrate layer 2 far away from the adhesive layer 3. The hydrophobic layer 1 may include one or more of the following hydrophobic polymers: polyvinylidene chloride, polyvinylidene fluoride, polytetrafluoroethylene, and polytrifluorochloroethylene. The hydrophobic layer 1 can effectively prevent the adsorption and dissolution of water vapor on the surface of the organic barrier film, and reduces the infiltration of water vapor.

In some embodiments, a matte layer 5 can be disposed on the first surface of the substrate layer 2, the matte layer 5 can be disposed on the surface of the substrate layer 2 far away from the adhesive layer 3, and the matte layer 5 may include a carrier and transparent particles. The carrier can be selected from one or more of epoxy resin, acrylate resin, silicone resin and polyurethane resin, and the material of the transparent particles can be selected from one or more of polyacrylate, polystyrene, polypropylene, polycarbonate, methyl methacrylate-butadiene-styrene terpolymer and styrene-acrylonitrile copolymer. The matte layer 5 is beneficial to improve the light transmission rate of the organic barrier film.

The preparation method of the hydrophobic layer 1 may include: disposing a second mixture including a hydrophobic polymer, scattering particles, a leveling agent, and an antifoaming agent on the second surface of the substrate layer 2. The preparation method of the matte layer 5 can refer to the prior art, and will not be described with detail in the present disclosure.

The present disclosure also provides a quantum dot device including a quantum dot layer and the aforesaid organic barrier film disposed on one surface or both surfaces of the quantum dot layer, wherein the organic barrier film includes a substrate layer 2, an adhesive layer 3 and an oxygen barrier layer 4 that are sequentially stacked, and the oxygen barrier layer 4 is disposed on the surface of the adhesive layer 3 close to the quantum dot layer.

In some embodiments, the hydrophobic layer 1 or the matte layer 5 is disposed on the surface of the substrate layer 2 far away from the quantum dot layer.

In some embodiments, a second adhesion layer is disposed between the quantum dot layer and the oxygen barrier layer 4 to improve the adhesion.

The raw material of the oxygen barrier layer can be prepared by the following steps: 10 g of fully hydrolyzed polyvinyl alcohol with a polymerization degree of 1700 was added into 90 g of deionized water, and heated at 95° C. for 1 h, and an appropriate amount of leveling agent and antifoaming agent were added after cooling to prepare the PVA coating solution with a solid content of 10%.

The raw material of the hydrophobic layer can be prepared by the following steps: the PVDC emulsion (Solvay 193D) was diluted to a solid content of 30%, and 10% PMMA diffusion particles with a particle size of about 5μm and an appropriate amount of wetting dispersant, antifoaming agent, leveling agent, and anti-settling agent were added, and water-resistant emulsion coating solution was obtained after ultrasonic stirring for 30 min.

### EXAMPLE 1

Acrylic acid, butyl acrylate, hydroxyethyl acrylate and a certain amount of deionized water were placed in a three-necked flask with stirrers and a condensing reflux tube, purged with nitrogen for 10 min, stirred and heated to 75° C., a certain amount of potassium persulfate aqueous solution was added, incubated for 8 h, and the flask was then cooled down to 30° C. The solid content of the product was measured, and then 0.2% (mass percentage) leveling agent, 0.1% antifoaming agent, 0.5% polycarbodiimide and 3% boric acid were added into the flask and an acrylate emulsion binder was obtained.

The aforesaid acrylate emulsion binder was coated on the surface of the PET substrate with a thickness of 100 μm, baked and cured at 120° C. for 3 min to form an adhesive layer with a thickness of 1 μm. Then, the aforementioned raw material of the oxygen barrier layer was coated on the adhesive layer, baked and cured at 120° C. for 3 minutes to form an oxygen barrier layer with a thickness of 5 μm. Then, an organic barrier film was obtained, its oxygen transmission rate was measured as 0.323 cm³/m²·24 h ·0.1 MPa, its water vapor transmission rate was measured as 0.548 g/m²·24 h, and the coating adhesion was measured as level 1 by 100 grid method.

The UV glue containing self-made red and green quantum dots was coated on the oxygen barrier layer of the aforesaid organic barrier film, another piece of the same organic barrier film was prepared, and the two pieces of organic barrier film were oppositely adhered to form a sandwich structure. After UV curing, a quantum dot film was obtained.

### EXAMPLE 2

Dehydrated polyethylene glycol adipate and dicyclohexylmethane diisocyanate were placed in a three-necked flask with stirrers and a condensing reflux tube, purged with nitrogen for 10 min, stirred and heated to 65° C. Dilaurel dibutyltin acid as catalyst was added into the flask, and the temperature was kept at 65° C. for 15 min, then raised to 85° C. and incubated for 1 h. Then, dimethylolpropionic acid was added into the flask, and the temperature was further kept for lh, then lowered to 50° C., triethylamine was added to the system and reacted for 30 min, and then appropriate amount of deionized water was added, stirred and emulsified at 3000 rpm at room temperature for 1 h to obtain a uniform blue-white emulsion. And then 0.1% (mass percentage) antifoaming agent, 0.3% aziridine and 1% boric acid were added into the flask, and a polyurethane emulsion binder was obtained.

The aforesaid polyurethane emulsion binder was coated on the surface of the PET substrate with a thickness of 100 μm, baked and cured at 120° C. for 3 min to form an adhesive layer with a thickness of 1 μm. Then, the aforementioned raw material of the oxygen barrier layer was coated on the adhesive layer, baked and cured at 120° C. for 3 minutes to form an oxygen barrier layer with a thickness of 5 μm. Then, an organic barrier film was obtained, its oxygen transmission rate was 0.284 cm³/m²·24 h·0.1 MPa, and its water vapor transmission rate was 0.641 g/m²·24 h, and the coating adhesion was measured as level 1 by 100 grid method.

The UV glue containing red and green quantum dots as Example 1 was coated on the oxygen barrier layer of the organic barrier film, another piece of the same organic barrier film was prepared, and the two pieces were oppositely adhered to form a sandwich structure. After UV curing, a quantum dot film was obtained.

### EXAMPLE 3

Neopentyl glycol, phthalic anhydride, adipic acid, sodium isophthalate-5-sulfonate, trimethylolpropane and dibutyltin oxide as catalyst were placed in a three-neck flask with stirrers and a condensing reflux tube, purged with nitrogen for 10 minutes, stirred and heated to 150° C., incubated for 1 hour, then heated to 180° C. and incubated for 1 hour, finally raised to 200° C., and subjected to a vacuum state by removing the by-product of water in the system. After the reaction was completed, the temperature was lowered to 80° C., and deionized water was added to the flask, and then 0.2% (mass percentage) leveling agent, 0.1% antifoaming agent, 3% methyl etherified hexamethylolmelamine and 10% sodium borate were added into the flask, and a polyester emulsion binder was obtained.

The aforesaid polyester emulsion binder was coated on the surface of the PET substrate with a thickness of 100 μm, baked and cured at 120° C. for 3 minutes to form an adhesive layer with a thickness of 1 μm. Then, the aforementioned raw material of the oxygen barrier layer was coated on the adhesive layer, baked and cured at 140° C. for 3 minutes to form an oxygen barrier layer with a thickness of 5 μm. Then, an organic barrier film was obtained, its oxygen transmission rate was measured as 0.351 cm³/m²·24 h·0.1 MPa, its water vapor transmission rate was measured as 0.488 g/m²·24 h, and the coating adhesion was measured as level 0 by the 100 grid method.

The UV glue containing the red and green quantum dots as Example 1 was coated on the oxygen barrier layer of the organic barrier film, another piece of the same organic barrier film was prepared, and the two pieces were oppositely adhered to form a sandwich structure. After UV curing, a quantum dot film was obtained.

### EXAMPLE 4

Acrylic acid, butyl acrylate, acrylonitrile and a certain amount of deionized water were placed in a three-necked flask with stirrers and a condensing reflux tube, purged with nitrogen for 10 min, stirred and heated to 75° C., a certain amount of potassium persulfate aqueous solution was added into the flask, incubated for 8 hours, and then the temperature was cooled down to 30° C. The solid content was measured. Then, 0.2% (mass percentage) leveling agent, 0.1% antifoaming agent, 0.5% polycarbodiimide and 3% sodium acrylate were added into the flask and an acrylate emulsion binder was obtained.

The aforesaid acrylate emulsion binder was coated on the surface of a PET substrate with a thickness of 100 μm, baked and cured at 120° C. for 3 min to form an adhesive layer with a thickness of 1 μm, and then the aforementioned raw material of the oxygen barrier layer was coated on the adhesive layer, baked and cured at 120° C. for 3 minutes to form an oxygen barrier layer with a thickness of 5 μm. The aforementioned raw material of the hydrophobic layer was coated on the other surface of the PET substrate, baked and cured at 120° C. for 3 minutes to obtain a hydrophobic layer with a thickness of 5 μm. Finally, an organic barrier film was obtained, its oxygen transmission rate was measured as 0.302 cm³/m²·24 h·0.1 MPa, and its water vapor transmission rate was 0.224 g/m²·24 h. The coating adhesion was measured as level 1 by 100 grid method.

The UV glue containing the red and green quantum dots as Example 1 was coated on the oxygen barrier layer of the organic barrier film, another piece of the same organic barrier film was prepared, and the two pieces of organic barrier film were oppositely adhered to form a sandwich structure. After UV curing, a quantum dot film was obtained.

### EXAMPLE 5

Acrylic acid, butyl acrylate, hydroxyethyl acrylate and a certain amount of deionized water were placed in a three-necked flask with stirrers and a condensing reflux tube, purged with nitrogen for 10 min, stirred and heated to 75° C., a certain amount of potassium persulfate aqueous solution was added into the flask, the reaction was performed at 75° C. for 8 hours, and then cooled down to 30° C. The solid content was measured, and then 0.2% (mass percentage) leveling agent, 0.1% antifoaming agent, 0.5% polycarbodiimide and 3% water-soluble titanate chelator were added into the flask and an acrylate emulsion binder was obtained.

The aforesaid acrylate emulsion binder was coated on the surface of the PET substrate with a thickness of 100 μm, baked and cured at 120° C. for 3 min to form an adhesive layer with a thickness of 1 μm, and then the aforementioned raw material of the oxygen barrier layer was coated on the adhesive layer, then baked and cured at 120° C. for 3 minutes to form an oxygen barrier layer with a thickness of 5 μm. The aforementioned raw material of the hydrophobic layer was coated on the other surface of the PET substrate, baked and cured at 120° C. for 3 minutes to obtain a hydrophobic layer with a thickness of 5 μm. Finally, an organic barrier film was obtained, its oxygen transmission rate was measured as 0.410cm³/m²·24 h·0.1MPa, and its water vapor transmission rate was 0.198 g/m²·24 h. The coating adhesion was measured as level 0 by 100 grid method.

The UV glue containing the red and green quantum dots as Example 1 was coated on the oxygen barrier layer of the organic barrier film, and another piece of the same organic barrier film was prepared. After UV curing, a quantum dot film was obtained.

### COMPARATIVE EXAMPLE 1

Methyl acrylate, butyl acrylate, styrene and a certain amount of deionized water were placed in a three-necked flask with stirrers and a condensing reflux tube, purged with nitrogen for 10 min, stirred and heated to 75° C., a certain amount of potassium persulfate aqueous solution was added into the flask, and the reaction was performed at 75° C. for 8 hours, and then cooled down to 30° C. The solid content was measured, and then leveling agent of 0.2% (mass percentage), antifoaming agent of 0.1%, polycarbodiimide of 0.5% and water-soluble titanate chelator of 3% were added into the flask and an acrylate emulsion binder was obtained.

The acrylate emulsion binder was coated on the surface of PET substrate with a thickness of 100 μm, baked and cured at 120° C. for 3 min to form an adhesive layer with a thickness of 1 μm, and then the aforementioned raw material of the oxygen barrier layer was coated on the adhesive layer, baked and cured at 120° C. for 3 minutes to form an oxygen barrier layer with a thickness of 5 μm. The aforementioned raw material of the hydrophobic layer was coated on the other surface of the PET substrate, baked and cured at 120° C. for 3 minutes to obtain a hydrophobic layer with a thickness of 5 μm. Finally, an organic barrier film was obtained, its oxygen transmission rate was measured as 0.422cm³/m²·24 h·0.1MPa, and its water vapor transmission rate was 0.178 g/m²·24 h. The coating adhesion was measured as level 3 by the 100 grid method.

The UV glue containing the red and green quantum dots as Example 1 was coated on the oxygen barrier layer of the organic barrier film, another piece of the same organic barrier film was prepared, and the two pieces were oppositely adhered to form a sandwich structure. After UV curing, a quantum dot film was obtained.

### COMPARATIVE EXAMPLE 2

Acrylic acid, butyl acrylate, hydroxyethyl acrylate and a certain amount of deionized water were placed in a three-necked flask with stirrers and a condensing reflux tube, purged with nitrogen for 10 min, stirred and heated to 75° C., a certain amount of potassium persulfate aqueous solution was added. The reaction was performed at 75° C. for 8 hours, and then cooled down to 30° C. The solid content was measured, and then appropriate amount of leveling agent and antifoaming agent were added and an acrylate emulsion binder was obtained.

The acrylate emulsion binder was coated on the surface of PET substrate with a thickness of 100 μm, baked and cured at 120° C. for 3 min to form an adhesive layer with a thickness of 1 μm. The aforementioned raw material of the oxygen layer was coated on the adhesive layer, baked and cured at 120° C. for 3 minutes to form an oxygen barrier layer with a thickness of 5 μm. The aforementioned raw material of the hydrophobic layer was coated on the other surface of the PET substrate, baked and cured at 120° C. for 3 minutes to obtain a hydrophobic layer with a thickness of 5 μm. Finally, an organic barrier film was obtained, and its oxygen transmission rate was measured as 0.387 cm³/m²·24 h·0.1MPa, and its water vapor transmission rate was 0.256 g/m²·24 h. The coating adhesion was measured as level 3 by the 100 grid method.

The UV glue containing the red and green quantum dots as Example 1 was coated on the oxygen barrier layer of the organic barrier film, another piece of the same organic barrier film was prepared, and the two were oppositely adhered to form a sandwich structure. After UV curing, a quantum dot film was obtained.

### COMPARATIVE EXAMPLE 3

Acrylic acid, butyl acrylate, hydroxyethyl acrylate and a certain amount of deionized water were placed in a three-necked flask with stirrers and a condensing reflux tube, purged with nitrogen for 10 min, stirred and heated to 75° C., a certain amount of potassium persulfate aqueous solution was added. The reaction was performed at 75° C. for 8 hours, and then cooled down to 30° C. The solid content was measured. Then leveling agent of 0.2% (mass percentage) and antifoaming agent of 0.1% by mass percentage were added and an acrylate emulsion binder was obtained.

The acrylate emulsion binder was coated on the surface of PET substrate with a thickness of 100 μm, baked and cured at 120° C. for 3 min to form an adhesive layer with a thickness of 1 μm, and then the aforementioned raw material of the oxygen barrier layer was coated on the adhesive layer, baked and cured at 120° C. for 3 minutes to form an oxygen barrier layer with a thickness of 5 μm. An organic barrier film was obtained. Its oxygen transmission rate was measured as 0.588 cm³/m²·24 h·0.1MPa, and its water vapor transmission rate was 1.207 g/m²·24 h. The coating adhesion was measured as level 4 by 100 grid method.

The UV glue containing the red and green quantum dots as Example 1 was coated on the oxygen barrier layer of the organic barrier film, another piece of the same organic barrier film was prepared, and the two pieces were oppositely adhered to form a sandwich structure. After UV curing, a quantum dot film was obtained.

### COMPARATIVE EXAMPLE 4

Acrylic acid, butyl acrylate, hydroxyethyl acrylate and a certain amount of deionized water were placed in a three-necked flask with stirrers and a condensing reflux tube, purged with nitrogen for 10 min, stirred and heated to 75° C., a certain amount of potassium persulfate aqueous solution was added. The reaction was performed at 75° C. for 8 hours, and then cooled down to 30° C. The solid content was measured, and then leveling agent of 0.2% (mass percentage), antifoam agent of 0.1%, polycarbodiimide of 0.5% and water-soluble titanate chelator of 3% were added and an acrylate emulsion binder was obtained.

The acrylate emulsion binder was coated on the surface of PET substrate with a thickness of 100 μm, baked and cured at 120° C. for 3 min to form an adhesive layer with a thickness of 1 μm, and then the aforementioned raw material of the oxygen layer was coated on the adhesive layer, baked and cured at 120° C. for 3 minutes to form an oxygen barrier layer with a thickness of 5 μm. Then, the aforementioned raw material of the hydrophobic layer was coated on the oxygen barrier layer, baked and cured at 120° C. for 3 minutes to obtain a hydrophobic layer with a thickness of 5 μm. An organic barrier film was obtained, its oxygen transmission rate was measured as 0.305 cm³/m²·24 h·0.1MPa, and its water vapor transmission rate was 0.427 g/m²·24 h. The coating adhesion was measured as level 2 by 100 grid method.

The UV glue containing the red and green quantum dots as Example 1 was coated on the hydrophobic layer of the organic barrier film, another piece of the same organic barrier film was prepared, and the two pieces were oppositely adhered to form a sandwich structure. After UV curing, the quantum dot film was obtained.

The oxygen transmission rate was tested according to GB/T 1038-2000 standard, the condition was 38° C./0% RH; the water vapor transmission rate was tested according to GB/T 21529 standard, and the condition was 38° C./90% RH. The quantum yield and stability of the quantum dot films produced according to the above examples and comparative examples were tested. The test results are shown in Table 1. Among them, the test method of the quantum yield was using 450 nm blue LED as the backlight source, using an integrating sphere to test the blue backlight spectrum and the spectrum through the quantum dot film, and using the integrated area of the spectrum to calculate the quantum yield. Quantum yield=(emission peak area of red quantum dots+emission peak area of green quantum dots)/(peak area of the blue backlight—peak area of the blue backlight that is not absorbed through the quantum dot film) * 100%. The test method for aging stability was as follows: the method for aging stability measurement mainly includes high temperature and illumination with 450 nm blue LED as the backlight source (70° C., 0.5 W/cm²), high temperature and high humidity storage (65° C./95% RH) and high temperature storage (85° C.). Under such aging conditions, the changes in the quantum yield of quantum dot film were recorded. Since quantum dots are very sensitive to moisture and oxygen, the measurement of the decay of quantum yield under the aging conditions of high temperature and high humidity storage (65° C./95% RH) and high temperature storage was focused. RH refers to relative humidity.

TABLE 1
Luminous properties of each quantum dot film

| | Parameters | | | |
|---|---|---|---|---|
| | Peel force of | | | |
| | quantum dot | | Quantum yield | |
| | film (tested by | | (65° C./ | Quantum yield |
| | T-typed tensile | Quantum | 95% RH) | (85° C.) |
| | machine) | yield | (after 500 h | (after 500 h |
| Items | (N) | (initial) | of aging) | of aging) |
| Example 1 | 10.5 | 100% | 94.7% | 96.8% |
| Example 2 | 10.3 | 101.2% | 94.3% | 98.0% |
| Example 3 | 12.5 | 101.8% | 95.1% | 95.4% |
| Example 4 | 9.8 | 103.3% | 98.2% | 97.7% |
| Example 5 | 11.7 | 99.8% | 97.8% | 96.3% |
| Comparative | 1 | 102.2% | 87.8% | 90.5% |
| Example 1 | | | | |
| Comparative | 0.8 | 100.5% | 83.5% | 92.1% |
| Example 2 | | | | |
| Comparative | 0.4 | 102.5% | 70.7% | 91.7 |
| Example 3 | | | | |
| Comparative | 3.3 | 98.8% | 77.4% | 95.4% |
| Example 4 | | | | |

The difference between Example 5 and Comparative Example 1 is that the polymer binder is different. The polymer binder in Example 5 includes hydroxyl groups, while the polymer binder of Comparative Example 1 does not contain hydroxyl group. The experimental data shows that the adhesion of the organic barrier film of Comparative Example I (level 3) is worse than the adhesion of the organic barrier film of Example 5 (level 0), and the peel force of the quantum dot film of Comparative Example 1 is smaller. It can be seen that the polymer binder containing a hydroxyl group or a functional group similar to the hydroxyl group plays an important role in improving the bonding performance of the adhesive layer. In addition, the quantum dot stability of the quantum dot film of Example 5 is also better than that of Comparative Example 1. It can be seen that the polymer binder containing a hydroxyl group or a functional group similar to the hydroxyl group has the effect of improving the water and oxygen barrier properties of the organic barrier film.

The difference between Example 5 and Comparative Example 2 is that there is no crosslinker or chelator in the adhesive layer of Comparative Example 2. The experimental data of Comparative Example 2 shows that the adhesion of the organic barrier film is poor, the peel force of the quantum dot film prepared is very small, and the stability of the quantum dots is poor. It can be seen that the crosslinker and the chelator play important roles in improving the adhesion of the organic barrier film and the barrier property of water and oxygen.

The difference between Example 5 and Comparative Example 3 is that there is no crosslinker or chelator in the adhesive layer of Comparative Example 3, and the organic barrier film does not include a hydrophobic layer. The oxygen transmission rate of the organic barrier film of Example 5 was measured as 0.410 cm³/m²·24 h·0.1 MPa, and the water vapor transmission rate was 0.198 g/m²·24 h, while the oxygen transmission rate of the organic barrier film of Comparative Example 3 was 0.588 cm³/m²·24 h·0.1 MPa, and the water vapor transmission rate was 1.207 g/m²·24 h. It can be seen that when there is no hydrophobic layer, if crosslinker or chelator is absent, it will lead to the reduction of the oxygen barrier properties of the organic barrier film, in particular, the water barrier properties. From the data in Table 1, it can also be seen that the stability and peel force of the quantum dot film of Comparative Example 3 are worse than those of Example 5, and the stability of the quantum dot film of Comparative Example 3 is even worse under a high humidity environment, we suggest that in the absence of a hydrophobic layer, water vapor penetrating through the film to the adhesive layer without chelator and crosslinker will result in colloidal swelling of the adhesive layer, leading to complete loss of the adhesion of the adhesive layer with the oxygen barrier layer, so that it will accelerate the penetration of water vapor and oxygen into the quantum dot layer in the sandwich structure from the lateral sides, causing the quantum dots to fail quickly.

The difference between Example 5 and Comparative Example 4 is that the hydrophobic layer of the quantum dot film of Comparative Example 4 is on the surface close to the quantum dot layer, and the oxygen barrier layer is disposed outside of the hydrophobic layer. From the experimental data of Comparative Example 4, it can be seen that the peel force of the quantum dot film is poor, and the stability of the quantum dots is also poor, indicating that the hydrophobic layer disposed outside the oxygen barrier layer is beneficial to improve the barrier properties of the organic barrier film; on the one hand, the adhesion improvement of the quantum dot layer to the oxygen barrier layer makes the peel force of the quantum dot film of Example 5 higher.

The foregoing descriptions are merely preferred embodiments of the present disclosure and are not intended to limit the present disclosure, and for those skilled in the art, the present disclosure may have various changes and modifications. Any modification, equivalent replacement, and improvement made in the spirit and principle of the present disclosure shall fall within the protection scope of the present disclosure.

1. An organic barrier film, comprising a substrate layer, an adhesive layer and an oxygen barrier layer that being sequentially stacked, wherein the oxygen barrier layer comprises polyvinyl alcohol, and chemical cross-linking is formed between the adhesive layer and the oxygen barrier layer.

2. The organic barrier film according to claim 1, wherein the organic barrier film comprises one of a hydrophobic layer disposed on a surface of the substrate layer far away from the adhesive layer and a matte layer disposed on a surface of'the substrate layer far away from the adhesive layer.

3. The organic barrier film according to claim 1, wherein a raw material for preparing the adhesive layer comprises a polymer binder, a crosslinker and a chelator, and chemical cross-linking is formed between the chelator and the polyvinyl alcohol.

4. The organic barrier film according to claim 3, wherein the chelator is selected from one or more of boric acid, sodium borate, sodium acrylate and titanate.

5. The organic barrier film according to claim 3, wherein the crosslinker is selected from one or more of polycarbodiimide, aziridine and hexamethoxymethylmelamine.

6. The organic barrier film according to claim 3, wherein a glass transition temperature of the polymer binder is less than 50° C.

7. A method for preparing the organic barrier film, comprising steps of:
providing a substrate layer having a first surface and a second surface opposite from the first surface:
disposing an adhesive layer on the first surface, and disposing an oxygen barrier layer on a surface of the adhesive layer far away from the substrate layer, wherein the oxygen barrier layer comprises polyvinyl alcohol, and chemical cross-linking is formed between the adhesive layer and the oxygen barrier layer.

8. The preparation method according to claim 7, wherein a preparation method of the adhesive layer comprises:
disposing a first mixture comprising a polymer binder, a crosslinker and a chelator on the first surface, and the chelator being used to form chemical cross-linking with the polyvinyl alcohol.

9. The preparation method according to claim 8, wherein the chelator is selected from one or more of boric acid, sodium borate, sodium acrylate and titanate.

10. The preparation method according to claim 8, wherein the crosslinker is selected from one or more of polycarbodiimide, aziri dine and methyletherified hexamethylolmelamine.

11. The preparation method according to claim 7, wherein the preparation method further comprises steps of:
disposing a hydrophobic layer on the second surface, or disposing a matte layer on the second surface.

12. The preparation method according to claim 7, wherein a preparation method of the oxygen barrier layer comprises: disposing a second mixture comprising a polyvinyl alcohol, water, an antifoaming agent and a leveling agent on a surface of the adhesive layer far away from the substrate layer.

13. A quantum dot device, comprising a quantum dot layer and an organic barrier film disposed on at least one surface of the quantum dot layer, wherein the organic barrier film is the organic barrier film according to claim 1, the organic barrier film comprises a substrate layer, an adhesive layer and an oxygen barrier layer that are sequentially stacked, and the oxygen barrier layer is disposed on a surface of the adhesive layer close to the quantum dot layer.

14. The organic barrier film according to claim 3, wherein the polymer binder comprises at least one of hydroxyl group, carboxyl group and amino group.

15. The organic barrier film according to claim 3, wherein the polymer binder is selected from one or more of polyester, polyurethane and polyacrylate.

16. The preparation method according to claim 8, wherein the polymer binder comprises at least one of hydroxyl group, carboxyl group, and amino group.

17. The preparation method according to claim 8, wherein the polymer binder is selected from one or more of polyester, polyurethane, and polyacrylate.

18. The preparation method according to claim 9, wherein a mass percentage of the chelator in the first mixture is 1%˜10%.

19. The preparation method according to claim 11, wherein the hydrophobic layer comprises a hydrophobic polymer, and the hydrophobic polymer is selected from one or more of polyvinylidene chloride, polyvinylidene fluoride, polytetrafluoroethylene and polytrifluoroethylene.

20. The quantum dot device according to claim 13, wherein the organic barrier film comprises one of a hydrophobic layer disposed on a surface of the substrate layer far away from the adhesive layer and a matte layer disposed on a surface of the substrate layer far away from the adhesive layer.
